(19) United States
(12) Patent Application Publication
(10) Pub. No.: US 2004/0117695 A1
(43) Pub. Date: Jun. 17, 2004

(54) Capacity indicating means and measuring method

(76) Inventor: Huang-Tsun Chen, Taipei (TW)

Correspondence Address: BRUCE H. TROXELL, SUITE 1404, 5205 LEESBURG PIKE, FALLS CHURCH, VA, 22041, US

(21) Appl. No.: 10/329,523

(22) Filed: Dec. 27, 2002

(51) Int. Cl. G11C 29/00

(52) U.S. Cl. 714/718

(57) ABSTRACT

The present invention is related to a capacity indicating means and measuring method, which applied on a portable storing means and comprises: a storing means, which has a plurality of addresses, each address has a plurality of bits, a capacity unit of the capacity indicating means is determined by power of a number of plural low bits of plural bits of 2, shown as 2^{(a number of plural low bits of plural bits)}; a mechanical capacity indicating means, whose at least one end has an electrical connection to the storing means, wherein at least one winding is in between the mechanical capacity indicating means and storing means for driving mechanical capacity indicating means when the winding being electrified. Therefore, mechanical capacity indicating means adopts a mechanical way to present how much the capacity is.

### BACKGROUND OF THE INVENTION

1. Field of the Invention

The present invention generally relates to a capacity indicating means and measuring method, especially the capacity indicating means and its measuring method applied to the present portable storing means; further that the means indicates storing capacity by using resources of connected computing system.

2. Description of the Prior Art

Due to the production of computer, the human culture has being brought into the third industrial revolution. Therefore, human being life is full of different kinds of facilities and computing products. For the facilities, lots of information is delivered via Internet platform and to everywhere in the earth suddenly; furthermore there is almost each corner can be reached for communication by wireless or blue tooth technology. For the products, tabletop computer, laptop computer and palm digital products are able to work for the functions mentioned above.

On the other hand, to rely on those powerful and convenient tools to bring us into the present enlightenment life, and a close step may be followed, which is the maintenance. Once the tools cannot work properly due to user's careless, the inconvenience is then brought into our life, because we are used to that type of life with those tools already. People, including those persons with professional knowledge, neglect the following discussed issue but it should not be ignored and does exist in our life.

The current portable storing means hardly includes a capacity indicating means, and the storing means may be read by a host (tabletop computer, notebook, personal digital device, digital equipment) to know its capacity. Therefore, the inconvenient is happened without the capacity indicating means. As the imagination, the portable storing means is full already and user is in a helpless environment, therefore the embarrassment is come about; furthermore, it is possible to have nothing for rebuilding a database or the like. As aforesaid, how to figure out the issue of indicating capacity in a portable storing means without going through a host is the topic of the present invention.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### SUMMARY OF THE INVENTION

The main object of the present invention is to offer a capacity indicating means and measuring method for the current portable storing means showing its storing capacity with reading via a host.

The other object of the present invention is to offer a capacity indicating means and measuring method for increasing the facilities of the current portable storing means and avoiding insufficient storing room.

The objects, spirits and advantages of the preferred embodiment of the present invention will be readily understood by the accompanying drawings and detailed descriptions.

### BRIEF DESCRIPTION OF THE DRAWINGS

FIG. 1 is a schematic diagram of a structure of a first preferred embodiment of the present invention.

FIG. 2 is a schematic diagram of a detail structure of the first preferred embodiment of the present invention.

FIG. 3 is a method of measuring capacity of the present invention.

FIG. 4A is a partial view of a mechanical capacity indicator of the present invention.

FIG. 4B is a partial view of another mechanical capacity indicator of the present invention.

FIG. 5 is a schematic diagram of a structure of a second preferred embodiment of the present invention.

### DETAILED DESCRIPTION OF THE INVENTION

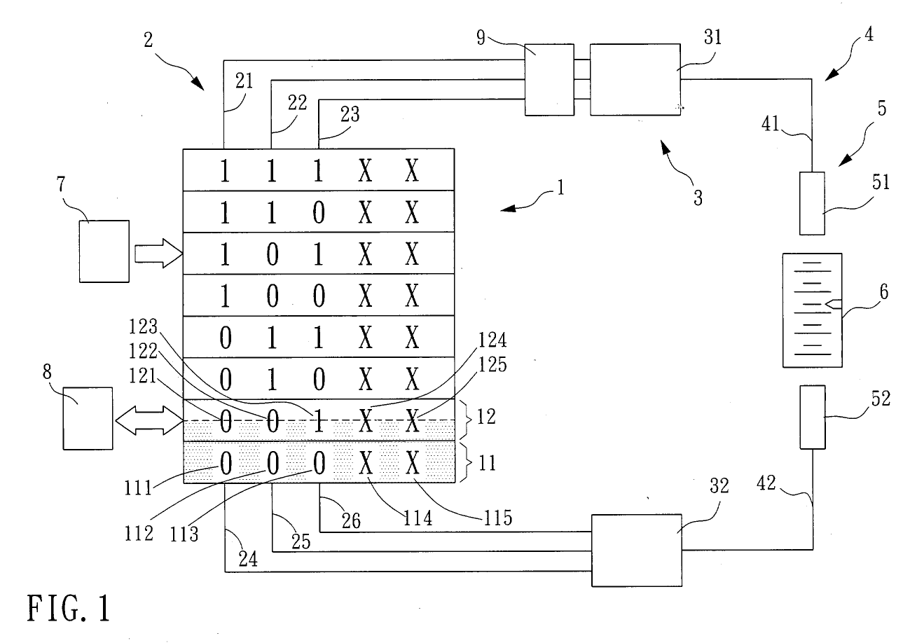

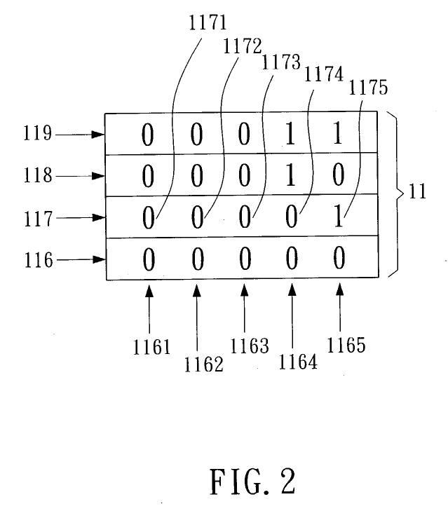

Please refer to FIG. 1, which is a schematic diagram of a structure of a first preferred embodiment of the present invention. The diagram shows there are only five bits in one address for easily describing the storing and measuring of the present invention. The realism may not be like this. The embodiment is a capacity indicating means applied on a portable storing means, which includes a storing means 1 with plural addresses, such as a first address 11 and a second address 12, and each address has plural bits, such as a first high bit 111, a second high bit 112, a third high bit 113, a second low bit 114, a first low bit 115, a first high bit 121, a second high bit 122, a third high bit 123, a second low bit 124, a first low bit 125, etc. The capacity unit is defined as the power of the number of plural low bits of plural bits of 2, whose formula is 2^{(the number of plural low bits of plural bits)}, and the plural bits are defined in an address. According to the embodiment, the low bit number is 2, so the formula is 2², that mean the capacity unit is 4. Please refer to FIG. 2, which is a schematic diagram of a detail structure of the first preferred embodiment of the present invention. The first address 11 has four sectional addresses, which are a first sectional address 116, a second sectional address 117, a third sectional address 118 and a fourth sectional address 119. Each sectional address stores single data, so a first sectional address 1161, a first sectional address 1162, a first sectional address 1163, a first sectional address 1164, a first sectional address 1165, a second sectional address 1171, a second sectional address 1172, a second sectional address 1173, a second sectional address 1174 and a second sectional address 1175 are partial addresses for storing each single part of data. Up to now, we would know values of the first sectional address 116 and the second sectional address 117 are 00000 and 00001, other sectional addresses are the like. Therefore after the four sectional addresses in the first address 11 being full, the more data is then stored into the sectional addresses in the second address 12, again other addresses are the like. For the embodiment, the shadow part shows that data is stored up to the middle part of the second address 12, and it will be discussed later; a mechanical capacity indicator 6, whose two ends electrically connect to the storing means 1, wherein two electromagnetic coils, a first electromagnetic coil 51 and a second electromagnetic coil 52, are separately placed between the two electrical connections. Connecting to a host to drive the mechanical capacity indicator 6 can activate the two electromagnetic coils. Furthermore there are an inverter 9 and a first digital/analog converter 31 in between the first electromagnetic coil 51 and the storing means 1; and again a second digital/analog converter 32 in between the second electromagnetic coil 51 and the storing means 1. It is that the storing means 1 transmits two signals, an upper stored capacity signal and a lower stored capacity signal, via signal lines 2. The inverter 9 inverts and the first digital/analog converter 31 converts the upper stored capacity signal to activate the first electromagnetic coil 51, and the second digital/analog converter 32 converts the lower stored capacity signal to activate the second electromagnetic coil 52, therefore both electromagnetic coils drive the mechanical capacity indicator 6 via magnetic forces for indicating the stored capacity. Wherein, the upper stored capacity signal is inverted based on the lower stored capacity signal. Theoretically, the first electromagnetic coil 51 and the second electromagnetic coil 52 being electrified to induce mechanical capacity indicator 6 is to use that the electromagnetic coil generates forces with magnetic objects when the coil being in conductive condition. A signal line number is equal to that a total bit number subtracts a set low bit number for outputting stored capacity signals from storing means 1. For instance, the set low bit number is 2 for the embodiment, and the total bit number is 5, then the signal lines of each end of storing means 1 are 3 after subtraction. So each end of storing means 1 for the embodiment has three signal lines, and the lines are placed from the first high bit, the second high bit, etc. A decoder 7 connects to storing means 1 for one-way communication from decoder 7 to storing means; meanwhile a plurality of buses 8 connects to storing means 1 as well for two-way communication between the buses and storing means 1, such buses 8 are as address bus, data bus, signal control bus, etc. Due to decoder 7 and buses 8 electrically connecting to storing means 1, storing means 1 is able to work for signal output.

As aforesaid, the shadow part in FIG. 1 shows the occupied capacity for the preferred embodiment. The first four sectional addresses in the first address 11 are full of data, and part of the second address 12 is occupied by data also, therefore the capacity for the embodiment is one unit, because the four sectional address in the second address 12 are not full of data, so it cannot be carried to 2. The lower stored capacity signal can be shown by 0 of a fourth signal line 24, 0 of a fifth signal line 25 and 1 of a sixth signal line 26; on the other hand, the upper stored capacity signal is shown by 0 of a first signal line 21, 0 of a second signal line 22 and 1 of a third signal line 23, then the signal is inverted by inverter 9, finally the original signal “001” is inverted to “110” and sent to the first digital/analog converter 31 and further to the first electromagnetic coil 51 and the mechanical capacity indicator 6 for showing capacity value. The function for inverter 9 is to enlarge the signal for obviously representing capacity value on mechanical capacity indicator 6.

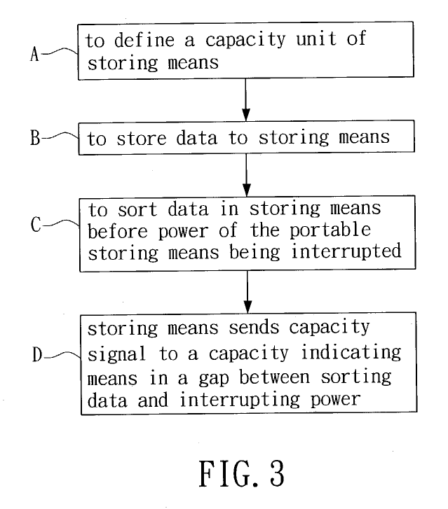

Please refer to FIG. 3, which is a method of measuring capacity of the present invention. The method is applied to measuring inside capacity of a capacity indicating means on a portable storing means, which comprises:

(1) to define a capacity unit of the portable storing means; that is, arranging addresses inside the capacity indicating means to store data, a storing means of the capacity indicating means has a plurality of addresses, and each address has its own plural bits, the arrangement may be according to the number of low bits for each single address and thus applied to the formula of 2^{(the number of low bits for each single address)}, the result is then defined as the number of sectional addresses for each single address, each sectional address stores data, and thus if each sectional address of a single address is full of data, which means one unit capacity has been occupied by data; otherwise it is still zero unit; further if a first address and some sectional addresses of a second address being full of data, which still means one unit;

(2) to put data into the storing means; that is, the storing means externally connects to a decoder, which adopts one-way communication to the storing means; additionally, the storing means connects to a plurality of buses, such as address bus, data bus, signal control bus, and so on, which adopt two-way communication to the storing means, thus data can be stored and read between them; on the other hand, power for storing means can be supplied by the decoder and buses;

(3) data in storing means is sorted before the power of the portable storing means being interrupted; that is, a system with aforesaid decoder and buses has an order to sort data in storing means firstly, then the data is arranged in each sectional address for correctly measuring capacity and avoiding empty sectional address;

(4) between data being sorted and power being cut, storing means sends a capacity signal to a mechanical capacity indicator; at least one end of the mechanical capacity indicator electrically connects to storing means, there is at least one electromagnetic coil in between mechanical capacity indicator and storing means for that the electromagnetic coil driving with mechanical capacity indicator; further, there is at least one digital/analog converter in between electromagnetic coil and one end of storing means for converting digital signal sent by storing means to analog signal, and the electromagnetic coil receives the analog signal to activate mechanical capacity indicator; besides, the number of signal lines is determined by a difference of a total bit number and a low bit number; theoretically, the electromagnetic coil being electrified to induce mechanical capacity indicator is to use that the electromagnetic coil generates forces with magnetic objects when the coil being in conductive condition.

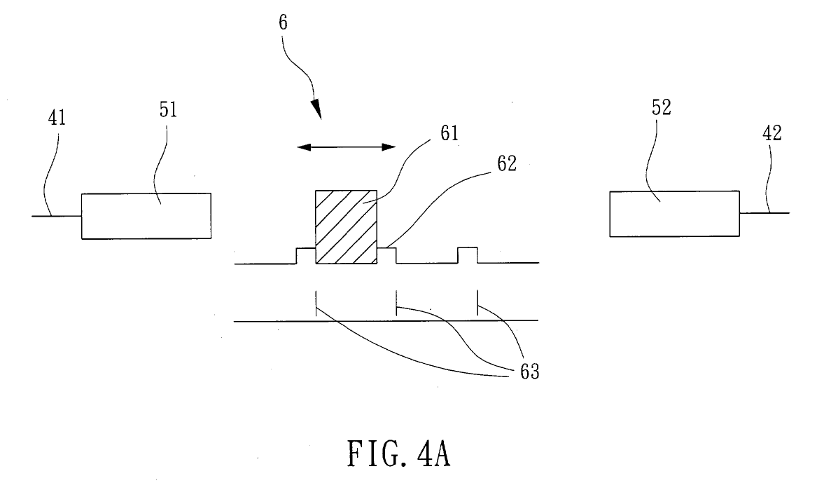

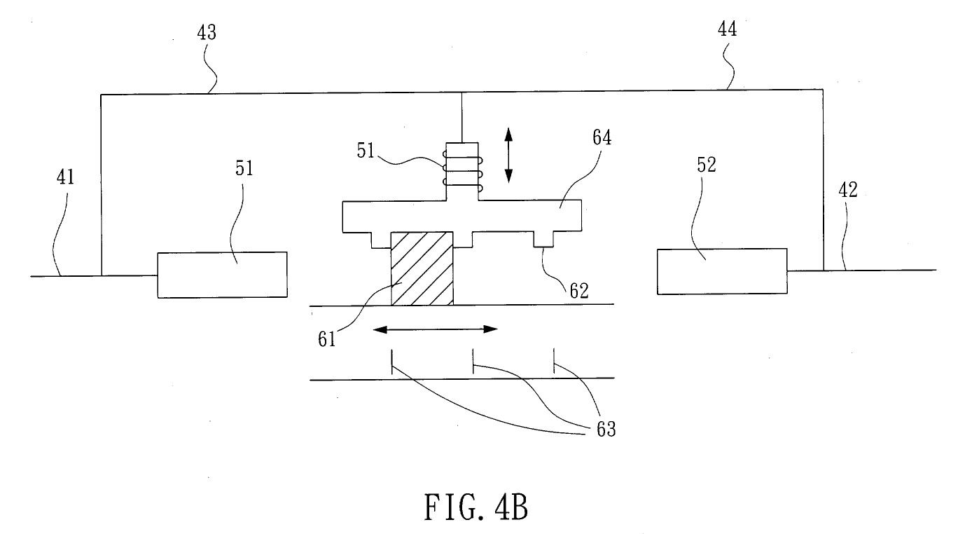

Referring to FIG. 4A, which is a partial view of a mechanical capacity indicator of the present invention, and FIG. 4B, which is a partial view of another mechanical capacity indicator of the present invention. So, there are two designs for mechanical capacity indicator 6, one is ladder type, shown as FIG. 4A, another is electromagnetic type, shown as FIG. 4B. In FIG. 4A, the first electromagnetic coil 51 and the second electromagnetic coil 52 individually receives analog signals from a first analog line 41 and a second analog line 42, thus both first electromagnetic coil 51 and second electromagnetic coil 52 act on a pointer 61. The pointer 61 moves back and forth, and a block 62 functions to stop pointer 61 when pointer 61 moving a distance. Therefore pointer 61 is stopped on a certain position when power is suddenly interrupted. The moving distance is based on graduation 63 to present capacity. In FIG. 4B, a block base 64 with plural blocks 62 is installed beyond pointer 61. Using the same theory as FIG. 4A to block and position pointer 61. When any analog signal being transmitted to a third electromagnetic coil 53 by means of the first analog line 41, the second analog line 42, a third analog line 43 and a fourth analog line 44, the block base 64 will be raised for pointer 61 freely moving back and forth. The moving distance may depend on the signals received by first electromagnetic coil 51 and second electromagnetic coil 52. Further, due to signal is last in a tiny period, block base 64 is raised and dropped down rapidly, therefore pointer 61 is fixed on a certain place. Finally, the moving distance shows the capacity in storing means.

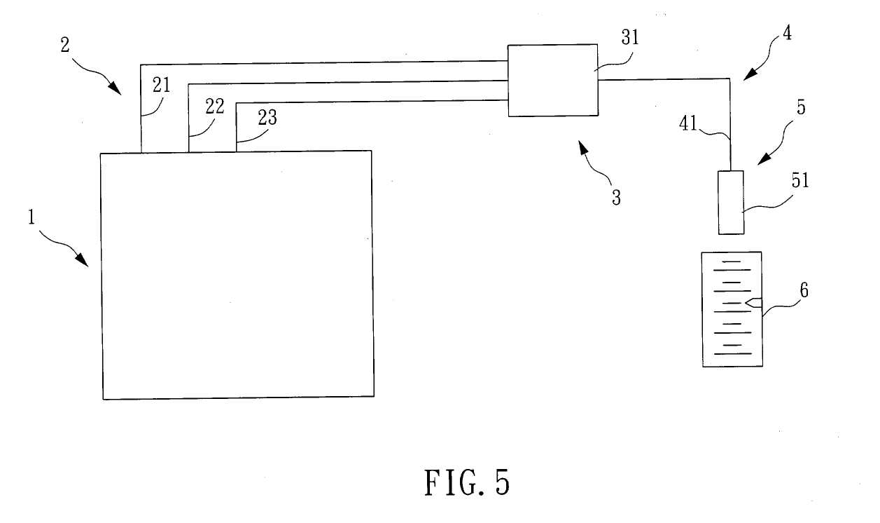

Referring to FIG. 5, which is a schematic diagram of a structure of a second preferred embodiment of the present invention. The preferred embodiment is simpler than the first preferred embodiment. The embodiment only has a set of signal lines, the first signal line 21, the second signal line 22 and the third signal line 23, the digital/analog converter 31, the first analog line 41, the first electromagnetic coil 51 and the mechanical capacity indicator 6. Because of lacking another set of signal lines, an inverter is not necessary to amplify signal, thus the structure is a lot of easier than the first embodiment. In FIG. 5, signal is transmitted by storing means 1 and through the set of signal lines to digital/analog converter 31. After converting digital signal to analog signal, the analog signal is thus sent to the first electromagnetic coil 51, the coil 51 finally acts on mechanical capacity indicator 6. After showing the capacity, the indicator 6 needs to be reset manually for next capacity measurement.

Although this invention has been disclosed and illustrated with reference to a particular embodiment, the principles involved are susceptible for use in numerous other embodiments that will be apparent to persons skilled in the art. This invention is, therefore, to be limited only as indicated by the scope of the appended claims.

What is claimed is:

1. A capacity indicating means applied on a portable storing means and comprising:
a storing means having a plurality of addresses, each address having a plurality of bits, a capacity unit of the capacity indicating means determined by power of a number of plural low bits of plural bits of 2, shown as 2^{(a number of plural low bits of plural bits)};
a mechanical capacity indicating means, whose at least one end having an electrical connection to the storing means, wherein at least one winding being in between the mechanical capacity indicating means and storing means for driving mechanical capacity indicating means when the winding being electrified.

2. The capacity indicating means as cited in claim 1, wherein the electrical connection is that at least one signal line functions to output storing capacity signal from the storing means, a number of the signal line is determined by that a total bit number subtracts a low bit number.

3. The capacity indicating means as cited in claim 1, wherein the winding is electromagnetic coil.

4. The capacity indicating means as cited in claim 1, wherein the winding being electrified to induce the mechanical capacity indicating means is to use that winding generates forces with magnetic objects when winding being in conductive condition.

5. The capacity indicating means as cited in claim 1, wherein the electrical connection between the mechanical capacity indicating means and the storing means further installs a digital/analog converting means.

6. The capacity indicating means as cited in claim 1, wherein the storing means externally connects to a decoder.

7. The capacity indicating means as cited in claim 6, wherein the decoder adopts one-way communication to storing means.

8. The capacity indicating means as cited in claim 1, wherein the storing means externally connects to a plurality of buses.

9. The capacity indicating means as cited in claim 8, wherein the buses adopt two-way communication to storing means.

10. The capacity indicating means as cited in claim 8, wherein the buses are address bus, data bus, signal control bus, and so on.

11. A capacity measuring method that measuring inside capacity of a storing means when the storing means applied on a portable storing means, the method comprising:
(a) to define a capacity unit of storing means;
(b) to store data to storing means;
(c) to sort data in storing means before power of the portable storing means being interrupted;
(d) storing means sends capacity signal to a capacity indicating means in a gap between sorting data and interrupting power.

12. The capacity measuring method as cited in claim 10, wherein the storing means externally connects to a decoder, and the decoder adopts one-way communication to storing means.

13. The capacity measuring method as cited in claim 10, wherein the storing means has a plurality of addresses, each address has plural bits.

14. The capacity measuring method as cited in claim 13, wherein the capacity unit of the capacity indicating means determined by power of a number of plural low bits of plural bits of 2, shown as 2^{(a number of plural low bits of plural bits)}.

15. The capacity measuring method as cited in claim 10, wherein the storing means externally connects to a plurality of buses and the buses adopt two-way communication to storing means.

16. The capacity measuring method as cited in claim 15, wherein the buses are address bus, data bus, signal control bus, and so on.

17. The capacity measuring method as cited in claim 10, wherein a mechanical capacity indicating means whose at least one end has an electrical connection to the storing means, wherein at least one winding is in between the mechanical capacity indicating means and storing means for driving mechanical capacity indicating means when the winding being electrified.

18. The capacity measuring method as cited in claim 17, wherein the electrical connection is that at least one signal line functions to output storing capacity signal from the storing means, a number of the signal line is determined by that a total bit number subtracts a low bit number.

19. The capacity measuring method as cited in claim 17, wherein the winding is electromagnetic coil.

20. The capacity measuring method as cited in claim 17, wherein the winding being electrified to induce the mechanical capacity indicating means is to use that winding generates forces with magnetic objects when winding being in conductive condition.

21. The capacity indicating means as cited in claim 17, wherein the electrical connection between the mechanical capacity indicating means and the storing means further installs a digital/analog converting means.
